(19) United States
(12) Patent Application Publication
(10) Pub. No.: US 2011/0146786 A1
(43) Pub. Date: Jun. 23, 2011

(54) PHOTOVOLTAIC MODULE INTERLAYER

(75) Inventors: Brian E. Cohen, Perrysburg, OH (US); Wenlai Feng, Perrysburg, OH (US)

(73) Assignee: First Solar, Inc., Perrysburg, OH (US)

(21) Appl. No.: 12/974,687

(22) Filed: Dec. 21, 2010

Related U.S. Application Data
(60) Provisional application No. 61/289,906, filed on Dec. 23, 2009.

(51) Int. Cl. H01L 31/0216; H01L 31/18

(52) U.S. Cl. 136/256; 438/84; 257/E31.008

(57) ABSTRACT

A photovoltaic module may include a substrate including a coating; and an interlayer placed in contact with the substrate, where the interlayer includes an acid-modified polyethylene.

### CLAIM FOR PRIORITY

This application claims priority under 35 U.S.C. §119(e) to U.S. Provisional Patent Application Ser. No. 61/289,906 filed on Dec. 23, 2009, which is hereby incorporated by reference.

### TECHNICAL FIELD

The present invention relates to photovoltaic modules and methods of production.

### BACKGROUND

Photovoltaic modules can include semiconductor material deposited over a substrate, for example, with a first layer serving as a window layer and a second layer serving as an absorber layer. A photovoltaic module can include an interlayer to separate the layers of the module from the environment.

### DESCRIPTION OF DRAWINGS

FIG. 1 is a schematic of a photovoltaic module.

FIG. 2 is a schematic of a photovoltaic module with an encapsulation frame.

FIG. 3 is a schematic of a photovoltaic module.

FIG. 4 is a schematic of a photovoltaic module with an encapsulation frame.

### DETAILED DESCRIPTION

A photovoltaic module can include a transparent conductive oxide layer adjacent to a substrate and layers of semiconductor material. The layers of semiconductor material can include a bi-layer, which may include an n-type semiconductor window layer, and a p-type semiconductor absorber layer. A layer can include a single layer or a plurality of layers, such as two layers to form a bi-layer. A layer or combinations of layers can cover all or a portion of the underlying layer or substrate and can be continuous or discontinuous. The layers can include a transparent conductive oxide (TCO) layer is typically deposited a substrate and a semiconductor bi-layer, which can include a semiconductor window layer and a semiconductor absorber layer.

The semiconductor absorber layer can absorb photons and generate electrical power. A buffer layer can be deposited between the TCO layer and the semiconductor window layer. A barrier layer can be incorporated between the substrate and the TCO layer. A back contact can be formed adjacent to the semiconductor absorber layer. A back support can be positioned adjacent to the back contact. The back support can include a glass sheet similar to the substrate. To protect the layers between the substrate and the back support, a material can be positioned in and around the space between the substrate and the back support. The material can include an interlayer material.

A photovoltaic module may include a substrate including a coating. The module may include an interlayer placed in contact with the substrate. The interlayer can include an acid-modified polyethylene. The interlayer may include an ethylene/vinyl acetate copolymer. The substrate may include a non-coated section, where the non-coated section is located substantially proximate to a perimeter of the substrate, and the interlayer is located on at least a part of the non-coated section. An edge of the substrate may be substantially free of the coating, and the substrate surface in the region free of coating may be substantially free of surface erosion. The interlayer may be located substantially proximate to a perimeter of the substrate. The photovoltaic module may include a cadmium-immobilizing agent proximate to the coating. The photovoltaic module may include a cadmium-immobilizing agent dispersed throughout the interlayer near a polymer-metal interface. The coating may include a cadmium telluride layer on a cadmium sulfide layer. The coating may include a transparent conductive oxide stack. The transparent conductive oxide stack may include a transparent conductive oxide layer on one or more barrier layers, and a buffer layer on the transparent conductive oxide layer. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, tin oxide, or combinations thereof. The transparent conductive oxide layer may include a layer of cadmium and tin. The buffer layer may include a zinc tin oxide, tin oxide, zinc oxide, or zinc magnesium oxide. The photovoltaic module may include a back contact metal on the cadmium telluride layer.

A method for manufacturing a photovoltaic module may include placing an interlayer in contact with a substrate. The substrate can include a coating. The method can include pressing the interlayer to the substrate. The interlayer can include an acid-modified polyethylene. The interlayer may include an ethylene/vinyl acetate copolymer. The substrate may include a non- coated section, where the non-coated section is proximate to the perimeter of the substrate. The method may include removing a portion of coating from the substrate, where the portion is proximate to the perimeter of the substrate, prior to placing an interlayer. The method may include laminating the coating. The method may include encapsulating the substrate, the coating, and the interlayer in a frame. The method may include depositing a cadmium-immobilizing agent proximate to the coating. The method may include dispersing a cadmium-immobilizing agent throughout the interlayer near a polymer-metal interface. The coating may include a cadmium telluride layer on a cadmium sulfide layer. The coating may include a transparent conductive oxide stack. The transparent conductive oxide stack may include a transparent conductive oxide layer on one or more barrier layers, and a buffer layer on the transparent conductive oxide layer. Each of the one or more barrier layers may include a silicon nitride, aluminum-doped silicon nitride, silicon oxide, aluminum-doped silicon oxide, boron-doped silicon nitride, phosphorous-doped silicon nitride, silicon oxide-nitride, tin oxide, or combinations thereof. The transparent conductive oxide layer may include a layer of cadmium and tin. The buffer layer may include a zinc tin oxide, tin oxide, zinc oxide, or zinc magnesium oxide.

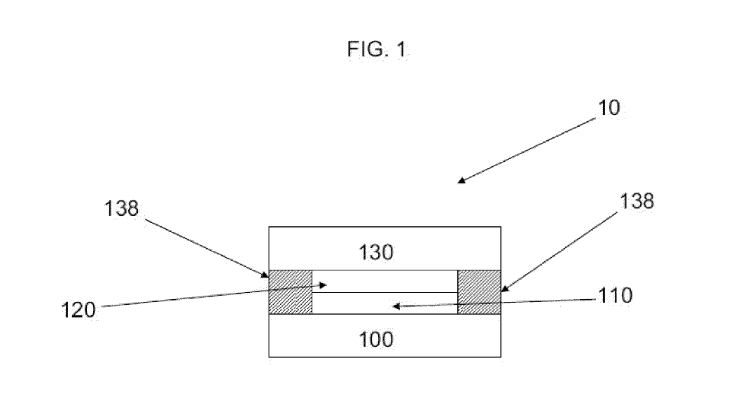

Referring to FIG. 1, a photovoltaic module 10 can include a front support 100 and a back support 130. Front support 100 and back support 130 can include any suitable material, including glass, for example, soda-lime glass. One or more layers 110 can be deposited adjacent to front support 100, which can serve as a first substrate, on top of which various layers may be added. Layer(s) 110 can include one or more device layers. For example, layer(s) 110 can include a cadmium telluride absorber layer adjacent to a cadmium sulfide window layer. Layer(s) 110 can include additional metal layers adjacent to the cadmium telluride absorber layer. Layer(s) 110 can also include a transparent conductive oxide layer, which may be part of a transparent conductive oxide stack. The transparent conductive oxide stack may include one or more barrier layers and a buffer layer, with the transparent conductive oxide layer positioned on the one or more barrier layers, and the buffer layer positioned on the transparent conductive oxide layer. One or more metal-immobilizing agents can be deposited adjacent to layer(s) 110. For example, a heavy metal-immobilizing agent 120 can be deposited adjacent to layer(s) 110.

Heavy metal-immobilizing agent 120 can include a precipitating agent, a complexing agent, a sorbent, or a stabilizing agent. The precipitating agent can include various suitable materials, including FeS, Na₂S, CaS, Ca(OH)₂, NaOH, CaHPO₄, Ca(H₂PO₄)₂, CaCO₃, CaSiO₃, or a combination thereof. The complexing agent can include various suitable materials, including imino groups, thiol groups, disulfides, carbamates, or acid groups. Examples include, but are not limited to, EDTA, cysteine, xanthates, trimercaptotriazines, di-n-propyldithiophosphates, or any combination thereof. Possible sorbents include, but are not limited to, zeolites (synthetic or natural, modified or non-modified), lignin, chitosan, dead biomass, fly ash, clay, apatite, metal oxides (hydrous or non-hydrous), zero valent iron, carbon, tannin-rich materials, or combinations thereof. The stabilization material can include a cementious material such as pozzolan. The heavy metal-immobilizing agent 120 can also be deposited within the laser scribes of any of layer(s) 110, or on either side of the front and back supports. Photovoltaic module 10 can also include one or more interlayers 138, positioned adjacent to layer(s) 110 on one or more non-coated sections of front and back supports 100 and 130.

Interlayer 138 can include any suitable material, including a thermoplastic. For example, interlayer 138 can include acrylonitrile butadiene styrene (ABS), acrylic (PMMA), celluloid, cellulose acetate, cycloolefin copolymer (COC), ethylene-vinyl acetate (EVA), ethylene vinyl alcohol (EVOH), fluoroplasics (PTFE), ionomers, Kydex®, liquid crystal polymer (LCP), polyacetal (POM), polyacrylates, polyacrylonitrile (PAN), polyamide (PA), polyamide-imide (PAI), polyaryletherketone (PAEK), polybutadiene (PBD), polybutylene (PB), polybutylene terephthalate (PBT), polycaprolactone (PCL), polychlorotrifluoroethylene (PCTFE), polyethylene terephthalate (PET), polycyclohexylene dimethylene terephthalate (PCT), polycarbonate (PC), polyhydroxyalkanoates (PHAs), polyketone (PK), polyester, polyethylene (PE), polyetheretherketone (PEEK), polyetherketoneketone (PEKK), polyetherimide (PEI), polyethersulfone (PES), polyethylenechlorinates (PEC), polyimide (PI), polyactic acid (PLA), polymethylpentene (PMP), polyphenylene oxide (PPO), polyphenylene sulfide (PPS), polyphthalamide (PPA), polypropylene (PP), polystyrene (PS), polysulfone (PSU), polytrimethylene terephthalate (PTT), polyurethane (PU), polyvinyl acetate (PVA), polyvinyl chloride (PVC), polyvinylidene chloride (PVDC), styrene-acrylonitrile (SAN), butyl rubber, or any combination thereof. Interlayer 138 may also include an acid-modified polyethylene. For example, interlayer 138 may include an ethylene/vinyl acetate copolymer, as opposed to the conventional EVA SET material. Experimental results showed that photovoltaic modules made with laser-edge-deleted glass (LED) and ethylene/vinyl acetate copolymer interlayers exhibited higher efficiency totals (over 11%) than conventional devices made with EVA SET interlayers and non-laser-edge-deleted glass. LED modules with ethylene/vinyl acetate copolymer interlayers also exhibited less current leakage (about 1.8 x 10^{×5}) than conventional counterparts, as well as higher fill factor (about 70%).

Interlayer 138 can be deposited during multiple stages of the fabrication process. For example, one or more interlayers 138 can be deposited on a non-coated, perimeter section of front support 100 following deposition of layer(s) 110, and back support 130 can be deposited thereafter. Alternatively, back support 130 can be deposited on layer(s) 110, and one or more interlayers 138 can be deposited between front support 100 and back support 130. Interlayer 138 can contact one or more non-coated sections of front and back supports 100 and 130, respectively. The non-coated sections of front support 100 can be obtained through any suitable method, including laser-edge deletion, where one or more layers of coating are removed from a substrate using a laser; sandblasting may also be used.

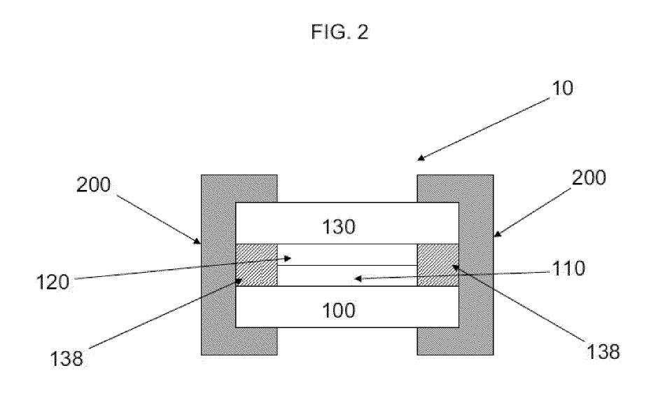

The cadmium telluride layer can be encapsulated within the module by materials designed to seal and hold the module together for many years and under a variety of conditions. The encapsulation material can help retain heavy metals present within the module by forming low solubility compounds that immobilize, chelate, adsorb, and/or fixate the cadmium and/or other heavy metals within the structure of the module to assist with handling and disposal. A photovoltaic module may also contain an encapsulation frame, with one or more interlayers between the front and back supports of the module. The one or more interlayers can be positioned on a non-coated section of the front support, which can include laser-edge deleted glass. The non-coated section of the front support can be located proximate to the perimeter of the front support. A back support can be positioned on top of the one or more coating layers and interlayers. It is also possible to deposit the back support immediately following deposition of any TCO or device layers, and to deposit interlayer material between the front and back supports, thereafter. Referring to FIG. 2, by way of example, photovoltaic module 10 can include an encapsulation frame 200 to hold the module layers together.

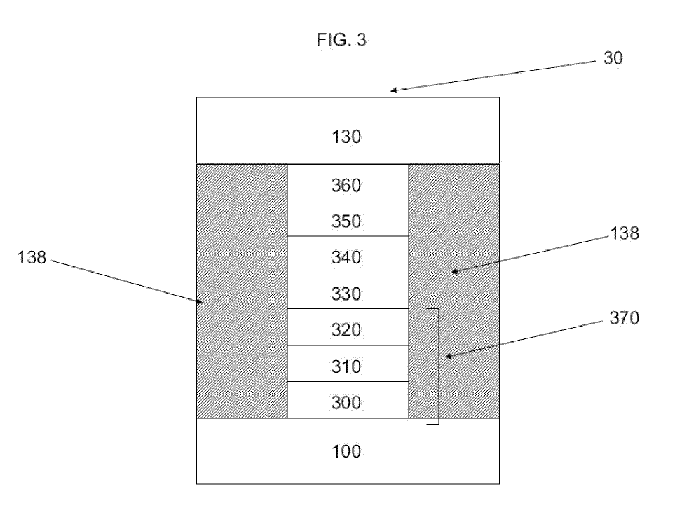

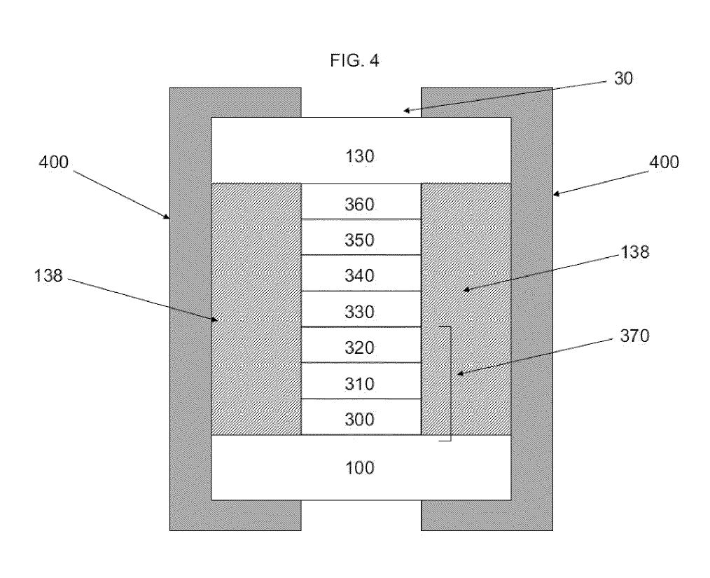

Referring to FIG. 3, a photovoltaic module 30 can include a barrier layer 300 adjacent to front support 100. Transparent conductive oxide layer 310 can be deposited adjacent to barrier layer 300. A buffer layer 320 can be deposited adjacent to transparent conductive oxide layer 310. Barrier layer 300, transparent conductive oxide layer 310, and buffer layer 320 can be deposited using any suitable deposition technique, including sputtering. Front support 100, barrier layer 300, transparent conductive oxide layer 310, and buffer layer 320 can be part of a transparent conductive oxide stack 370, which can be annealed prior to the deposition of subsequent layers. Cadmium sulfide layer 330 can be deposited adjacent to transparent conductive oxide stack 370 after annealing. Cadmium telluride layer 340 can be deposited onto cadmium sulfide layer 330. Cadmium sulfide layer 330 and cadmium telluride layer 340 can be deposited using any suitable deposition technique, including vapor transport deposition. One or more additional metal layers can be deposited adjacent to cadmium telluride layer 340. For example, a back contact metal 350 can be deposited adjacent to cadmium telluride layer 340. Back contact metal 350 can be deposited using any suitable deposition technique, including sputtering. Heavy metal-immobilizing agent 360, which can include a precipitating agent, a complexing agent, a sorbent, or a stabilizing agent, can be deposited adjacent to cadmium telluride layer 340 or adjacent to back contact metal 350. Heavy metal-immobilizing agent 360 can be suitable for immobilizing cadmium or other metals, such as mercury or lead. Heavy metal-immobilizing agent 360 can be deposited on a barrier layer. The barrier layer can be placed adjacent to a heavy metal-containing layer or adjacent to one or more additional metal layers. The barrier layer can also be patterned, and the heavy metal-immobilizing agent can be selectively placed on the barrier layer. The barrier layer can be a polymer or a ceramic and deposited by suitable means. Heavy metal-immobilizing agent 360 can also be deposited within cadmium telluride layer 340 within the laser scribes. A heavy metal-immobilizing agent can also be deposited as part of an interlayer 138 between front support 100 and back support 130, adjacent to one or more intermediate layers (i.e., layer(s) 110 from FIG. 1). Interlayer 138 can include any suitable interlayer material, including, for example, a heavy metal-immobilizing agent or thermoplastic. Referring to FIG. 4, heavy metal-immobilizing agent 360 can also be deposited directly onto back contact metal 350, or in the alternative, directly onto cadmium telluride layer 340.

The layers of photovoltaic module 30 can be aligned, heated, and bonded together by a lamination process. Lamination encapsulates the semiconductor layers, transparent conductive oxide stack layers, metal conductor, and any other layers of photovoltaic module 30, sealing the photovoltaic devices from the environment. Front support 100 and back support 130 can be bonded together with interlayers 138 through a lamination process, which may include a vacuum laminator. The photovoltaic module may undergo an IR heating step before or after lamination.

Photovoltaic devices/modules fabricated using the methods and apparatuses discussed herein may be incorporated into one or more photovoltaic arrays. The arrays may be incorporated into various systems for generating electricity. For example, a photovoltaic module may be illuminated with a beam of light to generate a photocurrent. The photocurrent may be collected and converted from direct current (DC) to alternating current (AC) and distributed to a power grid. Light of any suitable wavelength may be directed at the module to produce the photocurrent, including, for example, more than 400 nm, or less than 700 nm (e.g., ultraviolet light). Photocurrent generated from one photovoltaic module may be combined with photocurrent generated from other photovoltaic modules. For example, the photovoltaic modules may be part of a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

What is claimed is:

1. A photovoltaic module comprising:
a substrate comprising a coating; and
an interlayer placed in contact with the substrate, the interlayer comprising an acid-modified polyethylene.

2. The photovoltaic module of claim 1, wherein the interlayer comprises an ethylene/vinyl acetate copolymer.

3. The photovoltaic module of claim 1, wherein the substrate further comprises a non-coated section, wherein the non-coated section is located substantially proximate to a perimeter of the substrate, and the interlayer is located on at least a part of the non-coated section.

4. The photovoltaic module of claim 1, wherein an edge of the substrate is substantially free of the coating, and the substrate surface in the region free of coating material is substantially free of surface erosion.

5. The photovoltaic module of claim 1, wherein the interlayer is located substantially proximate to a perimeter of the substrate.

6. The photovoltaic module of claim 1, further comprising:
a cadmium-immobilizing agent proximate to the coating; or a cadmium-immobilizing agent dispersed throughout the interlayer near a polymer-metal interface.

7. The photovoltaic module of claim 1, wherein the coating comprises a cadmium telluride layer on a cadmium sulfide layer.

8. The photovoltaic module of claim 1, wherein the coating further comprises a transparent conductive oxide stack.

9. The photovoltaic module of claim 8, wherein the transparent conductive oxide stack comprises a transparent conductive oxide layer on one or more barrier layers, and a buffer layer on the transparent conductive oxide layer.

10. The photovoltaic module of claim 9, wherein each of the one or more barrier layers comprises a material selected from the group consisting of silicon nitride, aluminum-doped silicon nitride, silicon oxide, aluminum-doped silicon oxide, boron-doped silicon nitride, phosphorous-doped silicon nitride, silicon oxide-nitride, and tin oxide.

11. The photovoltaic module of claim 9, wherein the transparent conductive oxide layer comprises a layer of cadmium and tin.

12. The photovoltaic module of claim 9, wherein the buffer layer comprises a material selected from the group consisting of zinc tin oxide, tin oxide, zinc oxide, and zinc magnesium oxide.

13. The photovoltaic module of claim 9, further comprising a back contact metal on the cadmium telluride layer.

14. A method for manufacturing a photovoltaic module, the method comprising:
placing an interlayer in contact with a substrate, wherein the substrate comprises a coating; and
pressing the interlayer to the substrate, wherein the interlayer comprises an acid-modified polyethylene.

15. The method of claim 14, wherein the interlayer comprises an ethylene/vinyl acetate copolymer.

16. The method of claim 14, wherein the substrate further comprises a non-coated section, wherein the non-coated section is proximate to a perimeter of the substrate.

17. The method of claim 14, further comprising:
removing a portion of the coating from the substrate, wherein the portion is proximate to a perimeter of the substrate, prior to placing an interlayer;
laminating one or more layers;
encapsulating the substrate, the coating, and the interlayer in a frame;
depositing a cadmium-immobilizing agent proximate to the coating; or dispersing a cadmium-immobilizing agent throughout the interlayer near a polymer-metal interface.

18. The method of claim 14, wherein the coating comprises a cadmium telluride layer on a cadmium sulfide layer.

19. The method of claim 18, wherein the coating further comprises a transparent conductive oxide stack.

20. The method of claim 19, wherein the transparent conductive oxide stack comprises a transparent conductive oxide layer on one or more barrier layers, and a buffer layer on the transparent conductive oxide layer.
